(19) United States
(12) Patent Application Publication
(10) Pub. No.: US 2026/0322138 A1
(43) Pub. Date: Oct. 15, 2026

(54) SYSTEM CONTROL APPARATUS AND SYSTEM CONTROL METHOD FOR BATTERY CHARGING/DISCHARGING SYSTEM

(71) Applicant: LG ENERGY SOLUTION, LTD., Seoul (KR)

(72) Inventors: Seung-Choo KIM, Daejeon (KR); Myung-Hwan KIM, Daejeon (KR)

(21) Appl. No.: 19/479,996

(22) PCT Filed: Mar. 7, 2025
(86) PCT No.: PCT/KR2025/099630

§ 371 Date: Oct. 29, 2025

(30) Foreign Application Priority Data
Apr. 3, 2024 (KR) 10-2024-0045427

(51) Int. Cl. H02J 7/44; H02J 7/04; H02J 7/34; H02J 7/80; H02J 7/90

(52) U.S. Cl. CPC H02J 7/44; H02J 7/04; H02J 7/34; H02J 7/80; H02J 7/933; H02J 2207/20

(57) ABSTRACT

There are provided a system control apparatus and a system control method for a battery charging/discharging system. The system control apparatus is used for the battery charging/discharging system including first to m-th converters and first to m-th charging/discharging facilities respectively connected through first to m-th nodes on a shared power line. The system control apparatus includes first to m-th controllers to acquire first to m-th facility operation information including a measured voltage value and a measured current value respectively indicating a voltage and a current of a direct current (DC) power port of each of the first to m-th converters. An i-th controller is configured to determine an i-th target voltage value corresponding to an i-th converter based on i-th facility operation information, and transmit an i-th control command indicating the i-th target voltage value to the i-th converter.

### CROSS-REFERENCE TO RELATED APPLICATIONS

This application is a National Phase entry pursuant to 35 U.S.C. § 371 of International Application No. PCT/KR 2025/099630 filed on Mar. 7, 2025, which claims priority to and the benefit of Korean Patent Application No. KR 10-2024-0045427, filed on Apr. 3, 2024. The contents of the above-identified applications are herein incorporated by reference in their entireties.

### TECHNICAL FIELD

The present disclosure relates to a control technology for improving the efficiency of a charging/discharging process performed by a battery charging/discharging system.

### BACKGROUND

Recently, there has been a rapid increase in the demand for portable electronic products such as laptop computers, video cameras and mobile phones, and with the extensive development of electric vehicles, accumulators for energy storage, robots and satellites, many studies are being made on high performance batteries that can be repeatedly charged and discharged.

Batteries on the market now include nickel-cadmium batteries, nickel-hydrogen batteries, nickel-zinc batteries, lithium batteries and the like, and among them, lithium batteries have little or no memory effect, and thus they are gaining more attention than nickel-based batteries for their advantages that recharging can be done whenever it is convenient, the self-discharge rate is very low and the energy density is high.

Batteries are manufactured as finished products by performing an assembly process and a charging/discharging process in a sequential order. In the assembly process, a stack of a positive electrode, a negative electrode and a separator is housed in an outer packaging together with an electrolyte, followed by sealing. In the charging/discharging process, a predetermined charging/discharging procedure is performed on the batteries having undergone the assembly process. When the charging/discharging process is performed, solid electrolyte interphase (SEI) is formed on the negative electrode surface of the batteries, establishing the intended electrical properties.

The batteries having undergone the assembly process are sequentially transported on a battery tray to a battery charging/discharging system, and the battery charging/discharging system sequentially performs the charging/discharging process on the batteries in a first-in, first-out manner.

The battery charging/discharging system includes a plurality of power facility sets provided to take responsibility for the charging/discharging process for each battery tray. Because a large amount of power is required for the operation of the battery charging/discharging system, there is a risk of overloading on a specific power facility set. This risk may be mitigated to some extent by connecting the plurality of power facility sets in parallel to share the load.

However, during load sharing operation, the plurality of power facility sets cannot supply or regenerate equal power, and due to this limitation, larger or smaller power than power required for the specific power facility set is supplied.

In addition, the components (i.e., a converter and a charging/discharging facility) of each power facility set are directly or indirectly connected to each other via a wired communication network. This structure has an advantage of operating the components according to the condition of each component. For example, a signal notifying the start of a charging operation by the charging/discharging facility of the specific power facility set may be transmitted to the converter included in the same power facility set via the wired communication network, and accordingly, the converter may quickly supply the optimal charge power required for the charging/discharging facility. However, when all the converters and the charging/discharging facilities of the battery charging/discharging system are connected via the wired communication network, circuit wiring is complex and it requires a lot of time and financial resources to maintain and repair.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

The present disclosure solves the above-described problems, and therefore the present disclosure is directed to providing an apparatus and method for controlling each converter to allow a converter and a charging/discharging facility of each of a plurality of power facility sets to operate using power exchanged between them.

In addition, the present disclosure is directed to providing an apparatus and method without a wired communication network for the components (i.e., the converter and the charging/discharging facility) of each power facility set.

These and other objectives and advantages of the present disclosure may be understood from the following description and will become apparent from the embodiments of the present disclosure. Also, it will be easily understood that the objectives and advantages of the present disclosure may be realized by the appended claims and a combination thereof.

A system control apparatus for a battery charging/discharging system may include first to m-th converters and first to m-th charging/discharging facilities respectively connected through first to m-th nodes on a shared power line, the system control apparatus comprising: first to m-th controllers to acquire first to m-th facility operation information including a measured voltage value and a measured current value respectively indicating a voltage and a current of a direct current (DC) power port of each of the first to m-th converters, wherein an i-th controller of the first to m-th controllers is configured to: determine an i-th target voltage value corresponding to an i-th converter of the first to m-th converters based on i-th facility operation information of the first to m-th facility operation information, and transmit an i-th control command indicating the i-th target voltage value to the i-th converter, wherein m is a natural number of 2 or greater and i is a natural number equal to or smaller than m.

In certain embodiments of a system control apparatus for a battery charging/discharging system, the i-th controller may be configured to: perform the following operations for increasing a connection strength between an i-th charging/discharging facility of the first to m-th charging/discharging facilities and the i-th converter when a first control mode is set for the i-th converter, the operations including: an operation of determining an i-th node voltage value indicating a voltage of an i-th node of the first to m-th nodes based on the i-th facility operation information; and an operation of determining the i-th target voltage value based on a voltage difference between a predetermined first reference voltage value and the i-th node voltage value.

In certain embodiments of a system control apparatus for a battery charging/discharging system, the i-th controller may be further configured to: determine the i-th node voltage value by subtracting an i-th voltage drop value corresponding to the i-th measured current value from the i-th measured voltage value.

In certain embodiments of a system control apparatus for a battery charging/discharging system, the i-th controller may be further configured to: determine the i-th target voltage value by applying a predetermined positive correspondence relationship to the voltage difference to reduce the voltage difference.

In certain embodiments of a system control apparatus for a battery charging/discharging system, the i-th controller may be further configured to: switch a control mode for the i-th converter from the first control mode to a second control mode, wherein the second control mode is configured to reduce the connection strength between the i-th charging/discharging facility and the i-th converter when a duration of current flow from the i-th node to the i-th converter lasts for at least a first reference time while the first control mode is set for the i-th converter.

In certain embodiments of a system control apparatus for a battery charging/discharging system, the i-th controller may be further configured to: determine the i-th target voltage value to be a second reference voltage value when the second control mode is set for the i-th converter.

In certain embodiments of a system control apparatus for a battery charging/discharging system, the second reference voltage value may be equal to or greater than the predetermined first reference voltage value.

In certain embodiments of a system control apparatus for a battery charging/discharging system, the i-th controller may be further configured to: disable the second control mode and enter the first control mode when a duration of current flow from the i-th converter to the i-th node lasts for at least a second reference time while the second control mode is set for the i-th converter.

In certain embodiments of a system control apparatus for a battery charging/discharging system, an i-th shortest path resistance value may be smallest among first to m-th shortest path resistance values of the i-th converter, and wherein the first to m-th shortest path resistance values of the i-th converter correspond to shortest paths from the DC power port of the i-th converter to the DC power ports of the first to m-th charging/discharging facilities, respectively.

A battery charging/discharging system may include a system control apparatus described herein.

A system control apparatus for a battery charging/discharging system including first to m-th converters respectively connected to first to m-th nodes on a shared power line, and first to m-th charging/discharging facilities respectively connected to the first to m-th nodes, through first to m-th main lines, the system control method may include: acquiring, by first to m-th controllers included in the system control apparatus, first to m-th facility operation information including a measured voltage value and a measured current value respectively indicating a voltage and a current of a direct current (DC) power port of each of the first to m-th converters; determining, by an i-th controller of the first to m-th controllers, an i-th target voltage value corresponding to an i-th converter of the first to m-th converters based on i-th facility operation information of the first to m-th facility operation information; and transmitting, by the i-th controller, an i-th control command indicating the i-th target voltage value to the i-th converter, wherein m is a natural number of 2 or greater, and i is a natural number equal to or smaller than m.

In certain embodiments of a system control method, determining the i-th target voltage value may include performing the following steps for increasing a connection strength between an i-th charging/discharging facility of the first to m-th charging/discharging facilities and the i-th converter when a first control mode is set for the i-th converter, the steps comprising: determining an i-th node voltage value indicating a voltage of an i-th node of the first to m-th nodes based on the i-th facility operation information; and determining the i-th target voltage value based on a voltage difference between a predetermined first reference voltage value and the i-th node voltage value.

In certain embodiments of a system control method, determining the i-th target voltage value may include determining the i-th target voltage value by applying a predetermined positive correspondence relationship to the voltage difference to reduce the voltage difference.

In certain embodiments of a system control method, determining the i-th target voltage value further may include: switching a control mode for the i-th converter from the first control mode to a second control mode for reducing the connection strength between the i-th charging/discharging facility and the i-th converter when a duration of current flow from the i-th node to the i-th converter lasts for at least a first reference time.

In certain embodiments of a system control method, determining the i-th target voltage value may further include: determining the i-th target voltage value to be a second reference voltage value when the second control mode is set for the i-th converter.

According to at least one of the embodiments of the present disclosure, the apparatus and method provides for controlling each converter to allow the converter and the charging/discharging facility of each of the plurality of power facility sets included in the battery charging/discharging system to operate using power exchanged between them.

In addition, according to at least one of the embodiments of the present disclosure, it may be possible to eliminate a wired communication network for the components of each power facility set, thereby simplifying circuit wiring and saving time and financial resources required for maintenance and repair.

In addition, according to at least one of the embodiments of the present disclosure, when some of the plurality of converters are in power supply operation and the remaining converters are in power regeneration operation, regenerative power of each converter in power regeneration operation may be supplied to at least one converter in power supply operation, thereby reducing unnecessary line loss (for example, electrical energy lost by heat generated in the wire), regeneration loss (for example, electrical energy converted to alternating current (AC) power and escaping to the outside) and conversion loss (for example, electrical energy lost by heat generated during direct current (DC)-AC conversion operation of the converter).

The effects of the present disclosure are not limited to the aforementioned effects, and these and other effects will be clearly understood by those skilled in the art from the appended claims.

### BRIEF DESCRIPTION OF THE DRAWINGS

The accompanying drawings illustrate exemplary embodiments of the present disclosure and together with the following detailed description, serve to provide a better understanding of the technical aspects of the present disclosure, and thus the present disclosure should not be construed as being limited to the drawings.

FIG. 1 is a diagram referenced in describing the overall architecture of a battery charging/discharging system 10 according to an embodiment of the present disclosure.

FIG. 2 is a diagram referenced in describing the overall architecture of a battery charging/discharging system 10 according to an embodiment of the present disclosure.

FIG. 3 is a diagram referenced in describing the overall architecture of a battery charging/discharging system 10 according to an embodiment of the present disclosure.

FIG. 4 is a diagram referenced in describing a connection relationship of power facility sets.

FIG. 5 is a diagram referenced in describing a first control mode for a converter in each power facility set.

FIG. 6 is a diagram referenced in describing a second control mode for a converter in each power facility set.

FIG. 7 is a diagram referenced in describing an example of a voltage relationship of a converter, a node and a charger/discharger associated with a first control mode of a power facility set.

FIG. 8 is a diagram referenced in describing another example of a voltage relationship of a converter, a node and a charging/discharging facility associated with a first control mode of a power facility set.

FIG. 9 is a diagram referenced in describing another example of a voltage relationship of a converter, a node and a charger/discharger associated with a first control mode of a power facility set.

FIG. 10 is a diagram referenced in describing an example of a voltage relationship of a converter, a node and a charging/discharging facility associated with a second control mode of a power facility set.

FIG. 11 is a diagram referenced in describing a disadvantage of maintaining a control mode for a converter in a power regeneration operation at a first control mode.

FIG. 12 is a diagram referenced in describing an advantage of switching a control mode for a converter in a power regeneration operation from a first control mode to a second control mode.

FIG. 13 is a flowchart schematically illustrating a system control method according to another embodiment of the present disclosure.

FIG. 14 is a flowchart schematically illustrating an example of subroutines that may be included in step S1320 of FIG. 13.

FIG. 15 is a flowchart schematically illustrating another example of subroutines that may be included in step S1320 of FIG. 13.

### DETAILED DESCRIPTION

Hereinafter, exemplary embodiments of the present disclosure will be described in detail with reference to the accompanying drawings.

Therefore, the embodiments described herein and the illustrations shown in the drawings are exemplary embodiments of the present disclosure to describe the technical aspects of the present disclosure and not intended to be limiting, so it should be understood that a variety of other equivalents and modifications could be made thereto.

The terms including the ordinal numbers such as “first”, “second” and the like, are used to distinguish one element from another among various elements, and not intended to limit the elements by the terms.

Unless the context clearly indicates otherwise, the terms “comprise” and “include” when used in this specification, specify the presence of the stated elements, but do not preclude the presence or addition of one or more other elements. Additionally, the term “unit” as used herein refers to a processing unit of at least one function or operation, and may be implemented by hardware and software either alone or in combination.

In addition, throughout this specification, it will be further understood that when an element is referred to as being “connected to” another element, it may be directly connected to the other element or intervening elements may be present.

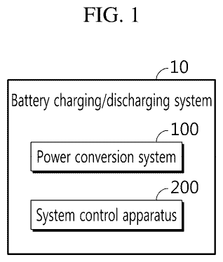

FIGS. 1 to 3 are diagrams referenced in describing the overall architecture of a battery charging/discharging system according to an embodiment of the present disclosure.

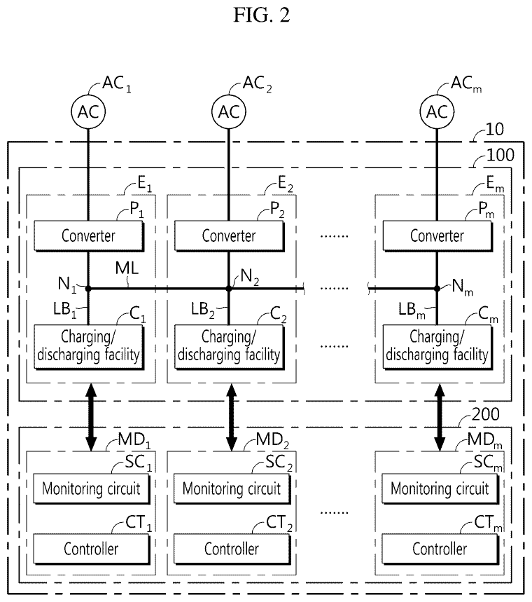

Referring to FIGS. 1 and 2, the battery charging/discharging system 10 includes a power conversion system 100 and a system control apparatus 200.

The power conversion system 100 includes power facility sets E₁~Eₘ. m is a natural number of 2 or greater. The power facility sets E₁~Em may be electrically coupled through a shared power line ML to enable bidirectional power supply. The term ‘line’ as used herein may include either a busbar or an electric cable, or a combination thereof.

Where i is a natural number that is equal to or smaller than m, the power facility set Eᵢ of the power conversion system 100 includes a converter Pi and a charging/discharging facility Cᵢ. Accordingly, the power conversion system 100 includes converters P₁~Pₘ and charging/discharging facilities C₁~Cₘ.

The converter Pᵢ may have an alternating current (AC) input/output port for coupling with an AC power network ACᵢ. The converter Pᵢ may have a direct current (DC) power port TPᵢ for coupling with the shared power line ML. The converter Pᵢ includes an AC-DC converter. The system control apparatus 200 may perform ON/OFF control for the AC-DC converter or adjust the magnitude of DC power supplied from the converter Pᵢ to the shared power line ML according to the condition of the AC power network ACᵢ.

The operation mode may include a power supply mode, a power regeneration mode and a rest mode. During operation in the power supply mode, the converter Pᵢ converts AC power supplied from the AC power network ACᵢ to DC power and supplies it to the shared power line ML. The voltage of DC power supplied from the converter Pᵢ to the shared power line ML may be maintained at a reference voltage (preset to, for example, 370 V) by feedback control. During operation in the power regeneration mode, the converter Pᵢ converts DC power supplied through the shared power line ML to AC power and supplies it to the AC power network ACᵢ. For reference, the converter may be referred to as a power conversion facility.

The charging/discharging facility Cᵢ may have a DC power port TCᵢ for coupling with the shared power line ML. The charging/discharging facility Cᵢ may have a charging/discharging port for coupling with a charging/discharging port of a battery tray. The charging/discharging facility Cᵢ may include at least one bidirectional DC-DC converter. The charging/discharging facility Cᵢ may relay bidirectional power transfer between the battery tray transported to the charging/discharging facility Cᵢ and the shared power line ML.

The DC power port TPᵢ of the converter Pᵢ and the DC power port TCᵢ of the charging/discharging facility Cᵢ may be electrically connected through a line LBᵢ. The line LBᵢ may be referred to as an ‘i-th main line’. The nodes Nᵢ~Nₘ shown in FIG. 2 indicate points of connection of the shared power line ML to lines LB₁~LBₘ. That is, the line LBᵢ is connected to the shared power line ML at the node Nᵢ.

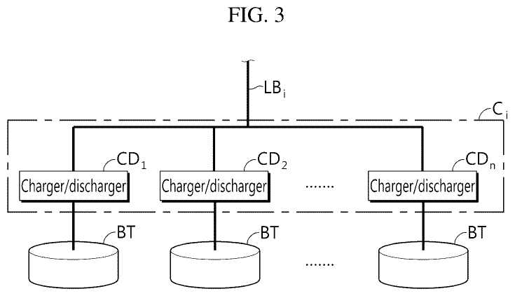

The charging/discharging facility Cᵢ may include at least one charger/discharger CD. FIG. 3 shows the charging/discharging facility Cᵢ including first to n-th chargers/dischargers CD₁~CDₙ (n is a natural number of 2 or greater). The first to n-th chargers/dischargers CD₁~CDₙ of the charging/discharging facility Cᵢ may independently or dependently operate in a battery charge mode, a battery discharge mode or a rest mode.

Each battery tray BT transported to the battery charging/discharging system 10 in a sequential order after the assembly process undergoes a charging/discharging process by any one charging/discharging facility of the battery charging/discharging system 10 in a first-in, first-out manner.

The charging/discharging process that the charging/discharging facility Ci performs on the battery tray BT includes at least one charging stage and at least one discharging stage performed in an alternating manner. When the charging/discharging process starts, the charging stage is performed first, and then the discharging stage is performed. Each charging stage may include at least one of a constant current charging procedure, a constant power charging procedure or a constant voltage charging procedure. Each discharging stage may include at least one of a constant current discharging procedure, a constant power discharging procedure or a constant voltage discharging procedure.

Additionally, the charging/discharging facility included in a certain power facility set may operate in the battery charge mode, the battery discharge mode and the rest mode, independently of the charging/discharging facility included in another facility set.

Referring to FIGS. 2 and 3, during operation in the battery charge mode, the charging/discharging facility Cᵢ may convert DC power supplied through the DC power port TCᵢ connected to the converter Pᵢ side to charge power having a predetermined voltage level, and output it to the DC power port TTᵢ connected to the battery tray BT side. During operation in the battery discharge mode, the charging/discharging facility Cᵢ may convert discharge power of the battery tray BT supplied through the DC power port TTᵢ to DC power having a predetermined voltage level, and output it to the DC power port TCᵢ.

When the charging/discharging facility Cᵢ includes the first to n-th chargers/dischargers CD₁~CDₙ, the operation of the charging/discharging facility Cᵢ in the battery charge mode may represent the charging/discharging facility Cᵢ in a charge dominant state. The charge dominant state may refer to a state in which the total charge power of the charging/discharging facility Cᵢ is larger than the total discharge power. In addition, the operation of the charging/discharging facility Cᵢ in the battery discharge mode may represent the charging/discharging facility Cᵢ in a discharge dominant state. The discharge dominant state may refer to a state in which the total charge power of the charging/discharging facility Ci is smaller than the total discharge power.

The total charge power of the charging/discharging facility Cᵢ may indicate power supplied to the charger/discharger(s) in the battery charge mode among the first to n-th chargers/dischargers CD₁~CDₙ. The total discharge power of the charging/discharging facility Cᵢ may refer to power regenerated from the charger/discharger(s) in the battery discharge mode among the first to n-th chargers/dischargers CD₁~CDₙ.

The system control apparatus 200 includes first to m-th facility management units MD₁~MDₘ. The first to m-th facility management units MD₁~MDₘ may independently perform monitoring and control operations for each of the first to m-th converters P₁~Pₘ without communication with one another.

An i-th facility management unit MDᵢ includes an i-th monitoring circuit SCᵢ and an i-th controller CTᵢ. Accordingly, the system control apparatus 200 includes first to m-th monitoring circuits SC₁~SCₘ and first to m-th controllers CT₁~CTₘ.

Hereinafter, for convenience of description, in the description that is shared between the first to m-th monitoring circuits SC₁~SCₘ, the symbol SC or SCᵢ may be affixed, and in the description that is shared between the first to m-th controllers CT₁~CTₘ, the symbol CT or CTᵢ may be affixed.

The first to m-th monitoring circuits SCᵢ~SCₘ may monitor the condition of the first to m-th converters P₁~Pₘ, respectively. Additionally, the first to m-th monitoring circuits SCᵢ~SCₘ may monitor the condition of the first to m-th charging/discharging facilities C₁~Cₘ, respectively.

Although FIG. 2 shows the i-th facility management unit MDᵢ physically independent from the i-th converter Pᵢ, the i-th facility management unit MDᵢ may be included in the i-th converter Pᵢ. In this case, the i-th facility management unit MDᵢ may be configured to monitor and control the power conversion circuit (for example, the AC-DC converter) of the i-th converter Pᵢ.

Although FIG. 2 shows the i-th monitoring circuit SCᵢ and the i-th controller CTᵢ physically independent of each other, this is provided by way of illustration, and the i-th monitoring circuit SCᵢ may be included in the i-th controller CTᵢ.

The monitoring circuit SCᵢ may measure the voltage and current of the DC power input and output to the converter Pᵢ. The monitoring circuit SCᵢ may measure the voltage and current of the DC power input and output to the charging/discharging facility Cᵢ.

The controller CTᵢ may include, in hardware, at least one of application specific integrated circuits (ASICs), digital signal processors (DSPs), digital signal processing devices (DSPDs), programmable logic devices (PLDs), field programmable gate arrays (FPGAs), microprocessors, or electrical units for performing other functions.

The controller CT; may have a built-in memory. The memory may include at least one type of storage medium of flash memory type, hard disk type, Solid State Disk (SSD) type, Silicon Disk Drive (SDD) type, multimedia card micro type, random access memory (RAM), static random access memory (SRAM), read-only memory (ROM), electrically erasable programmable read-only memory (EEPROM) or programmable read-only memory (PROM). The memory may store data and programs required for the operation by the controller CTᵢ. The memory may store data indicating the result of the operation by the controller CTᵢ.

The memory may pre-store a shortest path resistance value of each converter with respect to each charging/discharging facility of the power conversion system 100. In this specification, the shortest path resistance value from a certain converter to a certain charging/discharging facility may indicate the total resistance value of the shortest path connecting the DC power port of the converter to the DC power port of the charging/discharging facility.

Where x and y are different natural numbers equal to or smaller than m, both the shortest path resistance value of the converter P_{y} with respect to the charging/discharging facility Cₓ and the shortest path resistance value of the converter Pₓ with respect to the charging/discharging facility C_{y} may be smaller than the shortest path resistance value of the converter Pₓ with respect to the charging/discharging facility Cₓ. In addition, both the shortest path resistance value of the converter P_{y} with respect to the charging/discharging facility Cₓ and the shortest path resistance value of the converter Pₓ with respect to the charging/discharging facility C_{y} may be smaller than the shortest path resistance value of the converter P_{y} with respect to the charging/discharging facility C_{y}. That is, the i-th shortest path resistance value is the smallest one of first to m-th shortest path resistance values of the i-th converter Pᵢ.

The controller CT₁~CTₘ may collect measurement data from the monitoring circuits SC₁~SCₘ and monitor first to m-th facility operation information corresponding respectively to the first to m-th power facility sets E₁~_{E}m.

The first to m-th controllers CT₁~CTₘ may determine a target voltage value of the first to m-th converters P₁~Pₘ based on the first to m-th facility operation information, respectively. The method for determining the target voltage value of the i-th converter Pᵢ may rely on the operation mode individually set for the i-th converter Pᵢ.

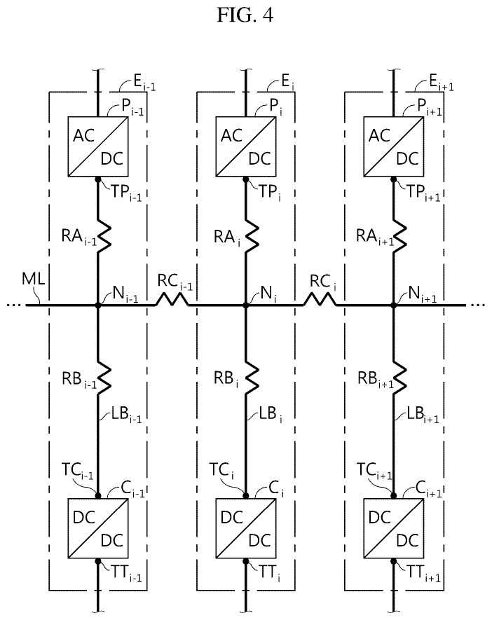

FIG. 4 is a diagram referenced in describing the connection relationship of the power facility sets. For convenience of description, FIG. 4 shows only three adjacent power facility sets Eᵢ₋₁, Eᵢ, Eᵢ₊₁ of the power facility sets E₁~Eₘ.

The memory may record line resistance values RA₁~RAₘ preset for the converters P₁~Pₘ, respectively.

Referring to FIG. 4, RAᵢ indicates the line resistance value of a line section (a portion of LBᵢ) from the DC power port TPᵢ of the converter Pᵢ to the node Nᵢ. RAᵢ₋₁ indicates the line resistance value of a line section (a portion of LBᵢ₋₁) from the DC power port TPᵢ₋₁ of the converter Pᵢ₋₁ to the node Nᵢ₋₁. RAᵢ₊₁ indicates the line resistance value of a line section (a portion of LBᵢ₊₁) from the DC power port TPᵢ₊₁ of the converter Pᵢ₊₁ to the node Nᵢ₊₁.

In addition, the memory may record line resistance values RB₁~RBₘ. In the line resistance values RB₁~RBₘ, RBᵢ may indicate a preset resistance value of a line section (a portion of LBᵢ) connecting the node Nᵢ to the DC power port TCᵢ of the charging/discharging facility Ci. Furthermore, the memory may record line resistance values RC₁~RCₘ₋₁. In the line resistance values RC₁~RCₘ₋₁, RCᵢ may indicate a preset resistance value of a line section (a portion of ML) connecting two adjacent nodes Nᵢ, _{Ni+1} of the nodes N₁~Nₘ.

The first control mode for the converter Pᵢ of the power facility set Eᵢ may be a control mode for increasing the connection strength between the converter Pᵢ and the charging/discharging facility Cᵢ. The first control mode may be referred to as a ‘droop operation mode’.

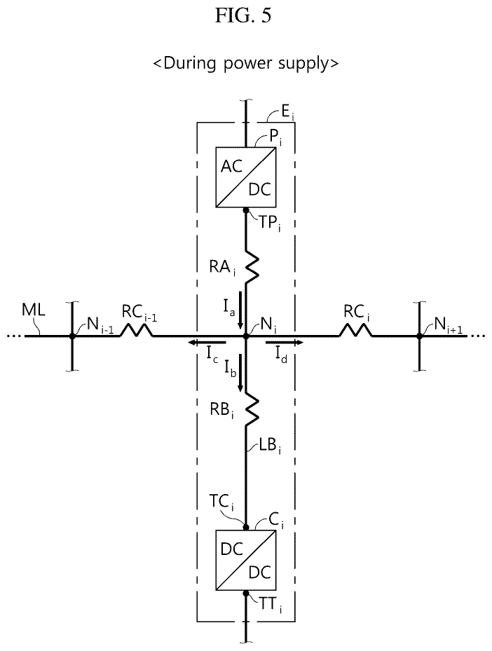

FIG. 5 is a diagram referenced in describing the first control mode for the converter in each power facility set. To help understanding, the description will be made based on a situation where the converter Pᵢ of the power facility set Eᵢ of the power facility sets E₁~Eₘ is in the power supply operation. The following description of the power facility set Eᵢ may be shared between each of the power facility sets E₁~Eₘ.

Referring to FIG. 5, the first to m-th controllers CT may set the control mode for the converter Cᵢ to the first control mode when the operation information of the converter Cᵢ meets a predetermined first mode setting condition.

The first to m-th controllers CT may determine an i-th node voltage value indicating the voltage of the i-th node Ni based on the i-th facility operation information while the first control mode is set for the converter Cᵢ. For reference, the first to m-th monitoring circuits SC may measure the voltage and current of the DC power port TPᵢ and generate i-th measurement data indicating an i-th measured voltage value and an i-th measured current value. The first to m-th controllers CT may determine the i-th node voltage value based on the i-th measurement data. Accordingly, it may be possible to eliminate a sensing circuit for measuring the voltage of the i-th node Nᵢ, thereby providing advantages of simplifying the circuit wiring and easing the maintenance and repair.

The first to m-th controllers CT determine the i-th node voltage value by subtracting an i-th voltage drop value corresponding to the i-th measured current value from the i-th measured voltage value. The relationship of the i-th measured voltage value, the i-th measured current value, the i-th voltage drop value and the i-th node voltage value may be represented by Equations 1-1 and 1-2 below.

V_{node}[i]=V_{P_t}[i]−V_{P_drop}[i] Equation 1-1

V_{P drop}[i]=I_{P t}[i]×RAᵢ Equation 1-2

In Equations 1-1 and 1-2, V_{node}[i] denotes the i-th node voltage value, V_{P_drop}[i] denotes the i-th voltage drop value, and I_{P_t}[i] denotes the i-th measured current value. V_{P_drop}[i] may be the result of applying Ohm's law to I_{P-t}[i] and RAᵢ. Here, I_{p_t}[i] having a positive value represents the flow of current from the DC power port TPᵢ to the node Nᵢ, and I_{P_t}[i] having a negative value represents the flow of current from the node Nᵢ to the DC power port TPᵢ.

The first control mode for the converter Cᵢ may be a control mode for matching the i-th node voltage value with a first reference voltage value. Accordingly, the first to m-th controllers CT determine the target voltage value of the converter Cᵢ based on a voltage difference between the first reference voltage value and the i-th node voltage value.

Ideally, the target voltage value for the converter Cᵢ and the measured voltage value of the DC power port TPᵢ are equal. However, due to signal delay or noise, a difference may exist between the target voltage value for the converter Cᵢ and the measured voltage value of the DC power port TPᵢ to a certain degree. In addition, the voltage of the i-th node Nᵢ may change under the influence of the operational state of the charging/discharging facility Cᵢ and the voltage of the adjacent nodes Nᵢ₋₁, Nᵢ₊₁. Accordingly, the controller CTᵢ may repeat the operation of determining (updating) the target voltage value of the converter Cᵢ periodically or aperiodically while the first control mode is set for the converter Cᵢ.

For example, in FIG. 5, assume that both the voltage value of the node Nᵢ₋₁ and the voltage value of the node Nᵢ₊₁ are kept equal to the first reference voltage value. According to Kirchhoff's current law, the current (Iₐ=I_{P_t}[i]) is equal to the sum of current I_{b}, current I_{c} and current I_{d}. In this instance, when the i-th node voltage value is also equal to the first reference voltage value, both a voltage difference between the node Nᵢ and the node Nᵢ₋₁ and a voltage difference between the node Nᵢ and the node Nᵢ₊₁ will be 0 [V]. Thus, the flow of current between the node Nᵢ and the node Nᵢ₋₁ and the flow of current between the node Nᵢ and the node Nᵢ₊₁ disappear (i.e., I_{c}=I_{d}=0[A]), thereby allowing the flow of current from any one of the converter Pᵢ and the charging/discharging facility Cᵢ to the other (i.e., Iₐ=I_{b}) . Accordingly, the converter Pᵢ is controlled by the controller CTᵢ according to the first control mode, resulting in stronger connection strength between the converter Pᵢ and the charging/discharging facility Cᵢ.

As opposed to the above-described example, assume that both the voltage value of the node Nᵢ₋₁ and the voltage value of the node Nᵢ₊₁ are larger than the first reference voltage value. In this case, I_{c} and I_{d} are smaller than 0 [A], and this represents the flow of current from the node Nᵢ₋₁ to the node Nᵢ and the flow of current from the node Nᵢ₊₁ to the node Nᵢ. Accordingly, Ia =Ip t[i] <Id, and the connection strength between the converter Pᵢ and the charging/discharging facility Cᵢ may not be weak.

While the converter Pᵢ and the charging/discharging facility Cᵢ are strongly connected to each other, the flow of current from the node Nᵢ to the node Nᵢ₋₁ or the node Nᵢ₊₁ may be suppressed, thereby allowing the power supply from any one of the converter Pᵢ and the charging/discharging facility Cᵢ to the other.

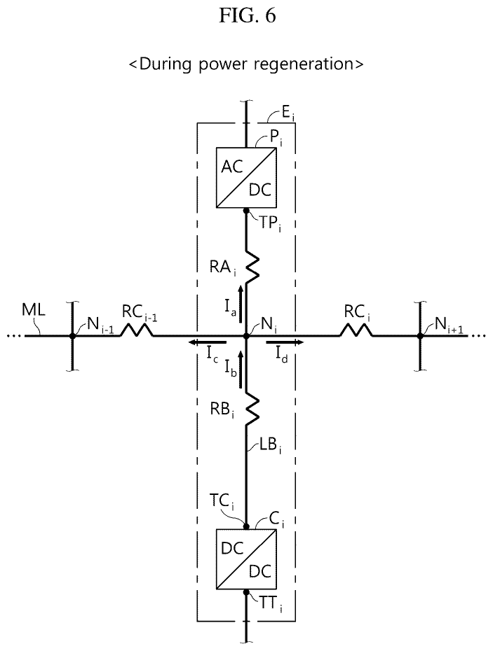

FIG. 6 is a diagram referenced in describing the second control mode for the converter in each power facility set. To help in understanding, the description will be made based on a situation where the converter Pᵢ of the power facility set Eᵢ of the power facility sets E₁~Eₘ is in power regeneration operation. The second control mode for the converter Pᵢ of the power facility set Eᵢ may be a control mode for reducing the connection strength between the converter Pᵢ and the charging/discharging facility Cᵢ. The following description of the power facility set Eᵢ may be shared between each of the power facility sets E₁~Eₘ.

Referring to FIG. 6, the controller CTᵢ may set the control mode for the converter Cᵢ to the second control mode when the operation information of the converter Cᵢ meets a predetermined second mode setting condition.

The controller CT; may keep the target voltage value of the converter Cᵢ equal to a second reference voltage value while the second control mode is set for the converter Cᵢ. The second reference voltage value may be equal to or larger than the first reference voltage value.

The second control mode for the converter Cᵢ may be a control mode for making the i-th node voltage value larger than the first reference voltage value.

For example, in FIG. 6, assume that both the voltage value of the node Nᵢ₋₁ and the voltage value of the node Nᵢ₊₁ are kept equal to the first reference voltage value. As opposed to FIG. 5, in FIG. 6, the sum of current (Iₐ=I_{P_t}[i]), current I_{b} and current I_{c} is equal to the current I_{d}. In this instance, because the i-th node voltage value is larger than the second reference voltage value, both the voltage difference between the node Nᵢ and the node Nᵢ₋₁ and the voltage difference between the node Nᵢ and the node Nᵢ₊₁ are larger than 0 [V]. Thus, the flow of current I_{c} from the node Nᵢ to the node Nᵢ₋₁ and the flow of current Iₐ from the node Nᵢ to the node Nᵢ₊₁ are generated, and as a result, the current (Iₐ=I_{P_}t[i] flowing from the node Nᵢ to the converter Pᵢ is smaller than the current I_{b} flowing from the charging/discharging facility Cᵢ to the node Nᵢ. Accordingly, as the converter Pᵢ is controlled by the controller CTᵢ according to the second control mode, the connection strength between the converter Pᵢ and the charging/discharging facility Cᵢ is reduced.

When the second control mode is set for the converter Pᵢ during the power regeneration operation of the converter Pᵢ, the flow of current from the node Nᵢ to the node Nᵢ₋₁ or the node Nᵢ₊₁ is not suppressed due to the low connection strength between the converter Pᵢ and the charging/discharging facility Cᵢ. Accordingly, some of the power supplied from the charging/discharging facility Cᵢ to the node Nᵢ is provided as the charge power required for the other charging/discharging facilities Cᵢ₋₁, Cᵢ₊₁. As a result, there are advantages of reducing the amount of regenerative power flowing back to the AC power network ACᵢ, and reducing the conversion loss inevitably accompanied by the power regeneration operation of the converter Pᵢ.

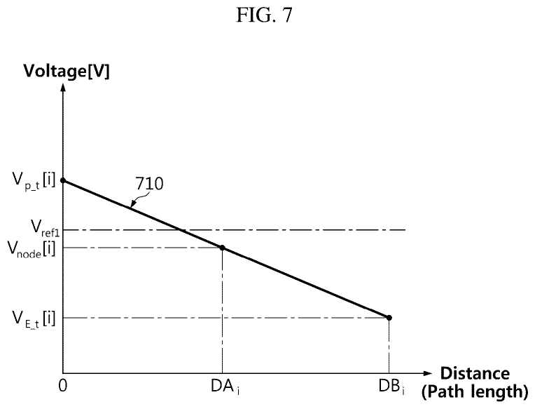

FIG. 7 is a diagram referenced in describing an example of a voltage relationship of the converter, the node and the charging/discharging facility associated with the first control mode of the power facility set. To help in understanding, the description will be made based on a situation where the converter Pᵢ set to the first control mode is in power supply operation.

Referring to FIG. 7, V_{P_t}[i] indicates the i-th measured voltage value, V_{node}[i] indicates the i-th node voltage value, V_{ref1} indicates the first reference voltage value, and V_{E-t}[i] indicates the voltage value of the DC power port TCᵢ of the charger/discharger Cᵢ. For reference, V_{E_t}[i] is not measured or estimated by the system control apparatus 200, and is for the purpose of convenience of description of the relationship between V_{P_t}[i] and V_{node}[i].

DAᵢ indicates the length from the DC power port TPᵢ to the node Nᵢ (corresponding to the line resistance value RAᵢ). DBᵢ indicates the length from the DC power port TPᵢ to the DC power port TCᵢ of the charger/discharger Cᵢ (corresponding to the total resistance value of the line LBᵢ=RAᵢ+RBᵢ). Because the converter Pᵢ is in power supply operation (for example, in FIG. 5, Iₐ>0 [A]), V_{P_t}[i] is the largest and V_{E_t}[i] is the smallest. Accordingly, the slope of a voltage curve 710 passing through V_{P_t}[i], V_{node}[i] and V_{E_t}[i] is a negative value.

In FIG. 7, V_{ref1}>V_{node}[i], and it is necessary to increase V_{node}[i]. To increase V_{node}[i], it is necessary to increase V_{P_t}[i]. Accordingly, the controller CTᵢ may increase the target voltage value by applying predetermined positive relationship data to the voltage difference between the first reference voltage value and the i-th node voltage value. When the target voltage value increases, V_{node}[i] increases toward V_{ref1} according to Equations 1-1 and 1-2, and the voltage difference between V_{node}[i] and V_{ref1} is reduced.

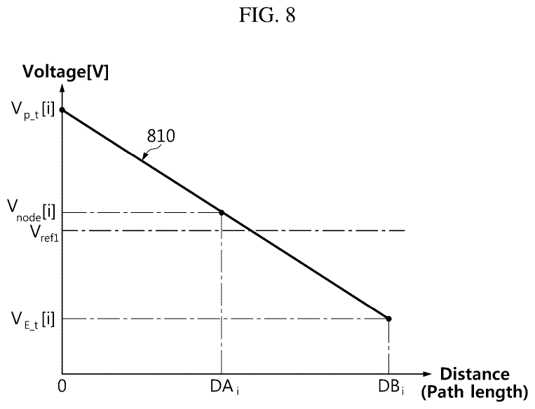

FIG. 8 is a diagram referenced in describing another example of a voltage relationship of the converter, the node and the charging/discharging facility associated with the first control mode of the power facility set. To help in understanding, the description will be made based on a situation where the converter Pᵢ set to the first control mode is in power supply operation.

Referring to FIG. 8, the slope of a voltage curve 810 passing through V_{P_t}[i], V_{node}[i] and V_{E_t}[i] is a negative value. However, in contrast to FIG. 7, in FIG. 8, V_{ref1}<V_{node}[i] <V_{E_t}[i], and it is necessary to reduce V_{node}[i]. When V_{node}[i] is not reduced, power may be dissipated through the adjacent nodes Nᵢ₋₁, Nᵢ₊₁.

To reduce V_{node}[i], it is necessary to reduce V_{P_t}[i]. Accordingly, the controller CTᵢ may reduce the target voltage value by applying predetermined positive relationship data to the voltage difference between the first reference voltage value and the i-th node voltage value. When the target voltage value is reduced, V_{node}[i] decreases toward V_{ref1} according to Equations 1-1 and 1-2, and the voltage difference between V_{node}[i] and V_{ref1} is reduced.

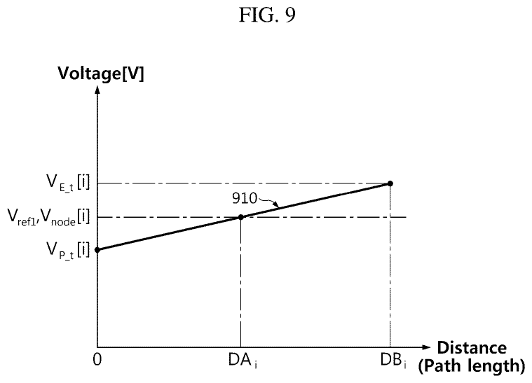

FIG. 9 is a diagram referenced in describing another example of as voltage relationship of the converter, the node and the charging/discharging facility associated with the first control mode of the power facility set. To help in understanding, the description will be made based on a situation where the converter Pᵢ set to the first control mode is in power regeneration operation.

Referring to FIG. 6 and FIG. 9 together, when the first control mode is set for the converter Pᵢ and the charging/discharging facility Cᵢ is in the discharge dominant state, the flow of current (Iₐ in FIG. 6) from the node Nᵢ to the converter Pᵢ is generated. Accordingly, the slope of a voltage curve 910 passing through V_{P_t}[i], V_{node}[i] and V_{E_t}[i] is a positive value.

V_{node}[i] may be larger than V_{P_t}[i], and V_{node}[i] may be nearly equal to V_{ref1}. When V_{node}[i] is nearly equal to the voltages of the adjacent nodes Nᵢ₋₁, Nᵢ₊₁, most of power regenerated from the charging/discharging facility Cᵢ may be converted into AC power through the converter Pᵢ without being used by the other charging/discharging facility operating in the battery charge mode.

To prevent the above-described negative result, it is necessary to disable the first control mode set for the converter Pᵢ and set the second control mode while the charging/discharging facility Cᵢ is in the discharge dominant state.

When the flow of current from the i-th node Nᵢ to the converter Pᵢ (see the direction of Iₐ in FIG. 6) lasts for a first reference time or longer, the controller CTᵢ may set the second control mode for the converter Pᵢ. For example, in response to the measured current value of the converter Pᵢ having the negative sign for the first reference time or longer, the controller CTᵢ may disable the first control mode for the converter Pᵢ and enter the second control mode for the converter Pᵢ.

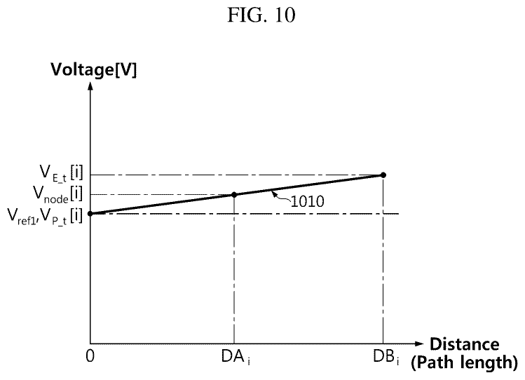

FIG. 10 is a diagram referenced in describing an example of a voltage relationship of the converter, the node and the charging/discharging facility associated with the second control mode of the power facility set. To help in understanding, assume that the control mode set for the converter Pᵢ is switched from the first control mode to the second control mode in the situation shown in FIG. 9.

When the second control mode is set for the converter Pᵢ, the controller CTᵢ determines the target voltage value of the converter Pᵢ to be equal to the second reference voltage value. As described above, the second reference voltage value is equal to or larger than the first reference voltage value, and V_{ref1} in FIG. 10 indicates the second reference voltage value.

Referring to FIG. 6 and FIG. 10 together, because the converter Pᵢ is in power regeneration operation, the slope of a voltage curve 1010 passing through V_{P_t}[i], V_{node}[i] and V_{E_t}[i] is a positive value.

When the voltage values of the adjacent nodes Nᵢ₋₁, Nᵢ₊₁ are almost equal to the first reference voltage value, power is transferred from the node Nᵢ of higher voltage to the adjacent nodes Nᵢ₋₁, Nᵢ₊₁ of lower voltage, and this represents that power regenerated from the charging/discharging facility Cᵢ may be supplied to the other charging/discharging facility operating in the battery charge mode.

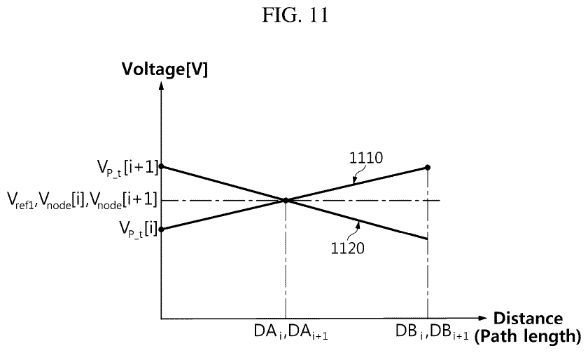

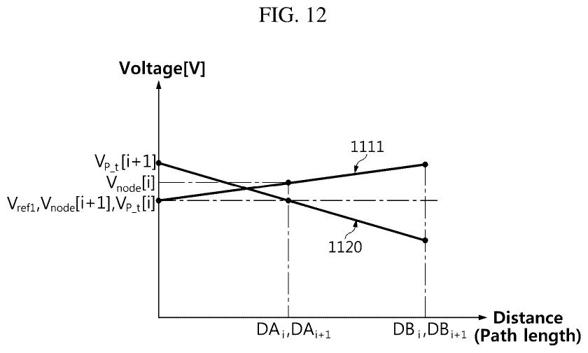

FIG. 11 is a diagram referenced in describing the disadvantage of maintaining the control mode for the converter in the power regeneration operation at the first control mode, and FIG. 12 is a diagram referenced in describing the advantage of switching the control mode for the converter in the power regeneration operation from the first control mode to the second control mode. For convenience of description, assume that the second reference voltage value is equal to the first reference voltage value, the converter Pᵢ is in the power regeneration operation, and the converter Pᵢ₊₁ is in the power supply operation.

The graph shown in FIG. 11 corresponds to a situation where the first control mode is set for both the converter Pᵢ and the converter Pᵢ₊₁.

Referring to FIG. 11, the slope of a voltage curve 1110 associated with the converter Pᵢ is a positive value, the slope of a voltage curve 1120 associated with the converter Pᵢ₊₁ is a negative value, and the two node voltage values V_{node}[i], V_{node}[i+1] are approximately equal to the first reference voltage value Vref₁ as assumed above.

Because the two node voltage values V_{node}[i], V_{node}[i+1] are equal to each other or not so much different from each other, no current may flow in a portion of the shared power line ML connecting the two nodes Nᵢ, Nᵢ₊₁. Accordingly, most of power regenerated from the charging/discharging facility Cᵢ is not supplied to the charging/discharging facility Cᵢ₊₁.

Subsequently, referring to FIG. 12, assume that the converter Pᵢ₊₁ operates under the same conditions as FIG. 11, and accordingly, a voltage curve 1120 is the same as the voltage curve 1120 of FIG. 11. In contrast, the slope of a voltage curve 1111 associated with the converter Pᵢ is gentler than the voltage curve 1110, the measured voltage value V_{P_t}[i] is equal to the first reference voltage value, the node voltage value V_{node}[i] is larger than the first reference voltage value, and this is the result of disabling the first control mode for the converter Pᵢ and setting the second control mode.

Accordingly, due to the voltage difference V_{node}[i]-V_{node}[i+1] between the two adjacent nodes Nᵢ, Nᵢ₊₁, the flow of current (see Ia in FIG. 6) from the node Nᵢ of higher voltage to the node Nᵢ₊₁ of lower voltage is generated. Accordingly, in contrast to the situation shown in FIG. 11, some of power regenerated from the charging/discharging facility Cᵢ is supplied to the charging/discharging facility Cᵢ₊₁.

The example of FIG. 12 shows a situation where the second reference voltage value is equal to the first reference voltage value, and when the second reference voltage value is larger than the first reference voltage value, the voltage difference V_{node}[i] V_{node}[i+1] is also larger than that of FIG. 12, thereby improving the power supply from the charging/discharging facility Cᵢ to the charging/discharging facility Cᵢ₊₁.

When the flow of current from the converter Pᵢ to the i-th node Nᵢ (see the direction of Ia in FIG. 5) lasts for a second reference time or longer in the second control mode set for the converter Pᵢ, the controller CTᵢ may set the first control mode for the converter Pᵢ. For example, in response to the measured current value of the converter Pᵢ having the positive sign for the second reference time or longer, the controller CTᵢ may disable the second control mode for the converter Pᵢ and enter the first control mode for the converter Pᵢ.

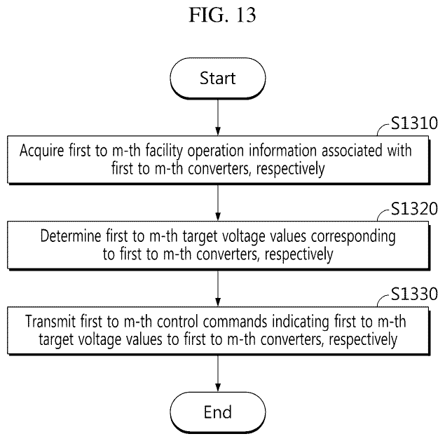

FIG. 13 is a flowchart schematically illustrating a system control method according to another embodiment of the present disclosure. The method according to FIG. 13 may be periodically or aperiodically performed by the system control apparatus 200 in a repeated manner while the charging/discharging process is performed by the battery charging/discharging system 10.

Referring to FIGS. 1 to 13, in step S1310, the first to m-th controllers CT₁~CTₘ acquire the first to m-th facility operation information associated with the first to m-th converters P₁~Pm, respectively. The i-th facility operation information includes the measured voltage value V_{P_t}[i] and the measured current value I_{P_t}[i] indicating the voltage and current of the DC power port TPᵢ of the converter Pᵢ, respectively.

In step S1320, the controller CT; determines the i-th target voltage value corresponding to the i-th converter Pᵢ of the first to m-th converters P₁~Pₘ, based on the i-th facility operation information of the first to m-th facility operation information. When the first to m-th controllers CT₁~CTₘ individually perform the step S1320, first to m-th target voltage values respectively corresponding to the first to m-th converters P₁~Pₘ may be determined.

In step S1330, the controller CTᵢ individually transmits an i-th control command indicating the i-th target voltage value to the i-th converter Pᵢ. Through the step S1330, first to m-th control commands may be transmitted to the first to m-th converters P₁~Pₘ, respectively. The i-th converter Pᵢ may adjust the voltage of the DC power port TPᵢ to match the i-th target voltage value in response to the i-th control command.

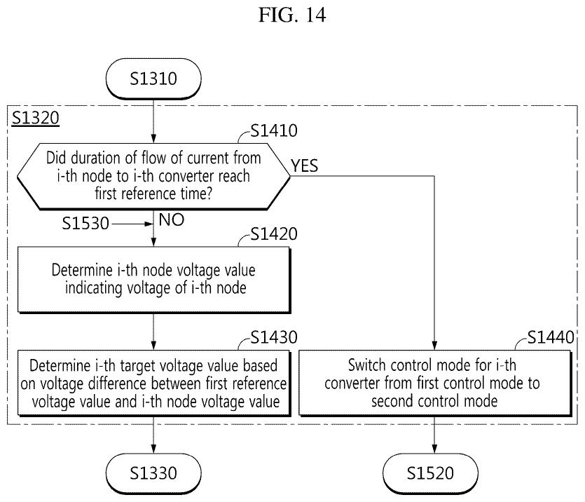

FIG. 14 is a flowchart schematically illustrating an example of subroutines that may be included in the step S1320 of FIG. 13. The method of FIG. 14 may be performed for each converter for which the first control mode is set among the first to m-th converters P₁~Pₘ.

Referring to FIGS. 1 to 14, in step S1410, the controller CTᵢ determines whether the duration of the flow of current from the i-th node Nᵢ to the i-th converter Pᵢ (see Iₐ in FIG. 6) reaches the first reference time. When a value of the step S1410 is “NO”, step S1420 may be performed. When the value of the step S1410 is “YES”, step S1440 may be performed. For reference, the first reference time may be preset to prevent the step S1440 from being unintentionally performed (i.e., switching from the first control mode to the second control mode) when the flow of current from the i-th node Nᵢ to the i-th converter Pᵢ is temporarily generated due to the influence of the voltage and/or current of the adjacent nodes Nᵢ₋₁, Nᵢ₊₁.

In the step S1420, the controller CTᵢ determines the i-th node voltage value V_{node}[i] indicating the voltage of the i-th node Nᵢ based on the i-th facility operation information.

In step S1430, the controller CTᵢ determines the i-th target voltage value based on the voltage difference between the first reference voltage value V_{ref1} and the i-th node voltage value V_{node}[i].

Where V_{ref1}>V_{node}[i], as V_{ref}−V_{node}[i] becomes larger, the larger i-th target voltage value may be determined. Where V_{ref1}<V_{node}[i], as V_{node}[i]−V_{ref1} becomes larger, the smaller i-th target voltage value may be determined.

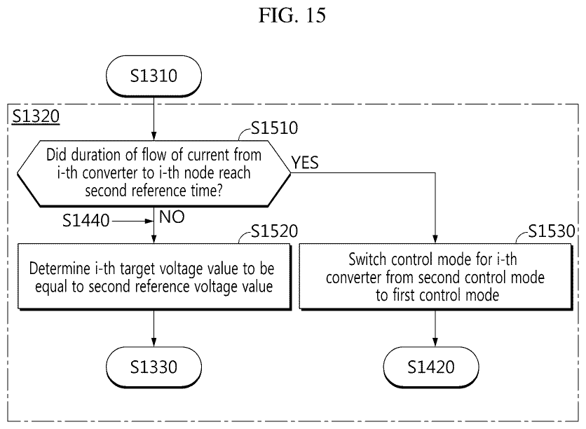

In the step S1440, the controller CTᵢ switches the control mode for the i-th converter Pᵢ from the first control mode to the second control mode. Setting the second control mode for the i-th converter Pᵢ is done to reduce the connection strength between the i-th charging/discharging facility Cᵢ and the i-th converter Pᵢ. When the step S1440 is completed, the method may move to step S1520 as described with reference to FIG. 15 below.

FIG. 15 is a flowchart schematically illustrating another example of subroutines that may be included in the step S1320 of FIG. 13. The method of FIG. 15 may be performed for each converter for which the second control mode is set among the first to m-th converters P₁~Pₘ.

Referring to FIGS. 1 to 15, in step S1510, the controller CTᵢ determines whether the duration of the flow of current from the i-th converter Pᵢ to the i-th node Nᵢ (see Iₐ in FIG. 5) reaches the second reference time. When a value of the step S1510 is “NO”, step S1520 may be performed. When the value of the step S1510 is “YES”, step S1530 may be performed. For reference, the second reference time may be preset to prevent the step S1530 from being unintentionally performed (i.e., switching from the second control mode to the first control mode) when the flow of current from the i-th converter Pᵢ to the i-th node Nᵢ is temporarily generated due to the influence of the voltage and/or current of the adjacent nodes Nᵢ₋₁, Nᵢ₊₁.

In the step S1520, the controller CTᵢ determines the i-th target voltage value to be equal to the second reference voltage value.

In the step S1530, the controller CTᵢ switches the control mode for the i-th converter Pᵢ from the second control mode to the first control mode. When the step S1530 is completed, the method may move to the step S1420 of FIG. 14.

The embodiments of the present disclosure as described above are not embodied only through the apparatus and method, and may be implemented through programs that perform the functions corresponding to the exemplary configurations of the present disclosure or recording media having the programs recorded thereon, and such implementation may be readily achieved by those skilled in the art from the disclosure of the embodiments previously described.

Although the present disclosure has been hereinabove described with regard to certain embodiments and drawings, the present disclosure is not limited thereto and it is should be understood to those skilled in the art that various modifications and changes may be made thereto within the scope of the technical aspects of the present disclosure. The scope of the invention is only limited by the appended claims and their equivalents.

Additionally, as many substitutions, modifications and changes may be made to the present disclosure as described above by those skilled in the art without departing from the technical aspects of the present disclosure, the present disclosure is not limited by the disclosed embodiments and the accompanying drawings, and some or all of the embodiments may be selectively combined to allow various modifications.

1. A system control apparatus for a battery charging/discharging system including first to m-th converters and first to m-th charging/discharging facilities respectively connected through first to m-th nodes on a shared power line, the system control apparatus comprising:
first to m-th controllers to acquire first to m-th facility operation information including a measured voltage value and a measured current value respectively indicating a voltage and a current of a direct current (DC) power port of each of the first to m-th converters,
wherein an i-th controller of the first to m-th controllers is configured to:
determine an i-th target voltage value corresponding to an i-th converter of the first to m-th converters based on i-th facility operation information of the first to m-th facility operation information, and
transmit an i-th control command indicating the i-th target voltage value to the i-th converter, wherein m is a natural number of 2 or greater and i is a natural number equal to or smaller than m.

2. The system control apparatus according to claim 1,
wherein the i-th controller is configured to:
perform the following operations for increasing a connection strength between an i-th charging/discharging facility of the first to m-th charging/discharging facilities and the i-th converter when a first control mode is set for the i-th converter, the operations including:
an operation of determining an i-th node voltage value indicating a voltage of an i-th node of the first to m-th nodes based on the i-th facility operation information; and
an operation of determining the i-th target voltage value based on a voltage difference between a predetermined first reference voltage value and the i-th node voltage value.

3. The system control apparatus according to claim 2,
wherein the i-th controller is further configured to:
determine the i-th node voltage value by subtracting an i-th voltage drop value corresponding to the i-th measured current value from the i-th measured voltage value.

4. The system control apparatus according to claim 2,
wherein the i-th controller is further configured to:
determine the i-th target voltage value by applying a predetermined positive correspondence relationship to the voltage difference to reduce the voltage difference.

5. The system control apparatus according to claim 2,
wherein the i-th controller is further configured to:
switch a control mode for the i-th converter from the first control mode to a second control mode, wherein the second control mode is configured to reduce the connection strength between the i-th charging/discharging facility and the i-th converter when a duration of current flow from the i-th node to the i-th converter lasts for at least a first reference time while the first control mode is set for the i-th converter.

6. The system control apparatus according to claim 5,
wherein the i-th controller is further configured to:
determine the i-th target voltage value to be a second reference voltage value when the second control mode is set for the i-th converter.

7. The system control apparatus according to claim 6,
wherein the second reference voltage value is equal to or greater than the predetermined first reference voltage value.

8. The system control apparatus according to claim 5,
wherein the i-th controller is further configured to:
disable the second control mode and enter the first control mode when a duration of current flow from the i-th converter to the i-th node lasts for at least a second reference time while the second control mode is set for the i-th converter.

919. The system control apparatus according to claim 1,
wherein an i-th shortest path resistance value is smallest among first to m-th shortest path resistance values of the i-th converter, and
wherein the first to m-th shortest path resistance values of the i-th converter correspond to shortest paths from the DC power port of the i-th converter to the DC power ports of the first to m-th charging/discharging facilities, respectively.

10. A battery charging/discharging system comprising the system control apparatus according to claim 1.

11. A system control method performed by a system control apparatus for a battery charging/discharging system including first to m-th converters respectively connected to first to m-th nodes on a shared power line, and first to m-th charging/discharging facilities respectively connected to the first to m-th nodes, through first to m-th main lines, the system control method comprising:
acquiring, by first to m-th controllers included in the system control apparatus, first to m-th facility operation information including a measured voltage value and a measured current value respectively indicating a voltage and a current of a direct current (DC) power port of each of the first to m-th converters;
determining, by an i-th controller of the first to m-th controllers, an i-th target voltage value corresponding to an i-th converter of the first to m-th converters based on i-th facility operation information of the first to m-th facility operation information; and
transmitting, by the i-th controller, an i-th control command indicating the i-th target voltage value to the i-th converter,
wherein m is a natural number of 2 or greater, and i is a natural number equal to or smaller than m.

12. The system control method according to claim 11,
wherein determining of the i-th target voltage value comprises:
performing the following steps for increasing a connection strength between an i-th charging/discharging facility of the first to m-th charging/discharging facilities and the i-th converter when a first control mode is set for the i-th converter, the steps comprising:
determining an i-th node voltage value indicating a voltage of an i-th node of the first to m-th nodes based on the i-th facility operation information; and
determining the i-th target voltage value based on a voltage difference between a predetermined first reference voltage value and the i-th node voltage value.

13. The system control method according to claim 12,
wherein determining the i-th target voltage value comprises:
determining the i-th target voltage value by applying a predetermined positive correspondence relationship to the voltage difference to reduce the voltage difference.

14. The system control method according to claim 12,
wherein determining the i-th target voltage value further comprises:
switching a control mode for the i-th converter from the first control mode to a second control mode for reducing the connection strength between the i-th charging/discharging facility and the i-th converter when a duration of current flow from the i-th node to the i-th converter lasts for at least first reference time.

15. The system control method according to claim 14,
wherein determining of the i-th target voltage value further comprises:
determining the i-th target voltage value to be a second reference voltage value when the second control mode is set for the i-th converter.
